(19) United States
(12) Patent Application Publication
(10) Pub. No.: US 2012/0043712 A1
(43) Pub. Date: Feb. 23, 2012

(54) MECHANISM AND METHOD FOR ALIGNING A WORKPIECE TO A SHADOW MASK

(75) Inventors: William Weaver, Austin, TX (US); Russell J. Low, Rowley, MA (US); Steven M. Anella, West Newbury, MA (US); Robert J. Mitchell, Winchester, MA (US)

(73) Assignee: VARIAN SEMICONDUCTOR EQUIPMENT ASSOCIATES, INC., Gloucester, MA (US)

(21) Appl. No.: 12/858,131

(22) Filed: Aug. 17, 2010

(51) Int. Cl. H01L 21/68; B23Q 3/00

(52) U.S. Cl. 269/304; 29/464

(57) ABSTRACT

A workpiece support is disclosed in which the platen, and thus the workpiece, can be tilted about at least two axis, which allows gravity to align the workpiece with a shadow mask in two orthogonal directions. In some embodiments, the workpiece support utilizes an axis of rotation that is orthogonal to the surface of the workpiece, in conjunction with a second axis that is parallel to the surface of the workpiece. Additionally, a method of aligning the workpiece using this workpiece support is also disclosed. Further, the workpiece support can be utilized to remove the workpiece from the support after implantation is completed.

### FIELD

This disclosure relates to a method and mechanism for aligning workpieces to a shadow mask, such as for use in an ion implantation process.

### BACKGROUND

An electronic device may be created from a workpieces that has undergone various processes. One of these processes may include introducing impurities or dopants to alter the electrical properties of the original workpiece. For example, charged ions, as impurities or dopants, may be introduced to a workpiece, such as a silicon wafer, to alter electrical properties of the workpiece. One of the processes that introduces impurities to the workpiece may be an ion implantation process.

An ion implanter is used to perform ion implantation or other modifications of a workpiece. A block diagram of a conventional ion implanter is shown in FIG. 1. Of course, many different ion implanters may be used. The conventional ion implanter may comprise an ion source 102 that may be biased by a power supply 101. The system may be controlled by controller 120. The operator communicates with the controller 120 via user interface system 122. The ion source 102 is typically contained in a vacuum chamber known as a source housing (not shown). The ion implanter system 100 may also comprise a series of beam-line components through which ions 10 pass. The series of beam-line components may include, for example, extraction electrodes 104, a 90° magnet analyzer 106, a first deceleration (D1) stage 108, a 70° magnet collimator 110, and a second deceleration (D2) stage 112. Much like a series of optical lenses that manipulate a light beam, the beam-line components can manipulate and focus the ion beam 10 before steering it towards a workpiece or wafer 114, which is disposed on a workpiece support 116.

In operation, a workpiece handling robot (not shown) disposes the workpiece 114 on the workpiece support 116 that can be moved in one or more dimensions (e.g., translate, rotate, and tilt) by an apparatus, sometimes referred to as a “roplat” (not shown). Meanwhile, ions are generated in the ion source 102 and extracted by the extraction electrodes 104. The extracted ions 10 travel in a beam-like state along the beam-line components and implanted on the workpiece 114. After implanting ions is completed, the workpiece handling robot may remove the workpiece 114 from the workpiece support 116 and from the ion implanter 100.

Referring to FIG. 2, there is shown a block diagram illustrating one embodiment of a workpiece support 116 used to support the workpiece 114 during the ion implantation process. In this embodiment, the workpiece 114 is mounted on a platen 175, such as by electrostatic force. The platen 175 is rotatably connected to structure 185. In some embodiments, the platen 175 is hinged to structure 185 such that the platen 175 and workpiece 114 may pivot along path 183. For clarity, the axis about which the platen 175 rotates is referred to as the x-tilt axis, and allows the workpiece to be tilted to allow angled implants. In some embodiments, the structure 185 is also able to rotate about a second axis 182, known as the y-axis tilt axis. Using rotation about these two axes, it is possible to place the workpiece 114 at any desired angle relative to the ion beam 10. In some embodiments, the structure 185 may also be able to move up and down, such as parallel to second axis 182, in order to perform scanned implants.

In some embodiments, it is desirable to place a shadow mask in front of the workpiece 114 to perform a patterned implant. This shadow mask must be aligned with the workpiece, in one direction or in both the x and y directions, such that the mask is properly positioned. In some embodiments, the mask is aligned to the workpiece. In other embodiments, the shadow mask is roughly aligned to the platen, and the workpiece is then precisely aligned with the shadow mask. FIG. 3 shows a shadow mask 195 and a workpiece 114. Alignment features 197 are positioned on the side of workpiece 114 to help align the shadow mask 195 with the workpiece 114. Similarly, alignment features 198 are positioned on the bottom side of the workpiece 114 to help alignment with the shadow mask 195 in that direction. In this embodiment, the shadow mask 195 is assumed to be fixed, while the workpiece 114 can be moved relative to the shadow mask 195 and the alignment features 197, 198. However, in other embodiments, the workpiece 114 is kept in a fixed position and the shadow mask 195 is moved relative to the workpiece 114.

It would be beneficial if the shadow mask 195 could be easily aligned with the workpiece 114. Referring back to FIG. 2, it can be seen that the workpiece 114 can be aligned with the shadow mask 195 using alignment features 198, by tilting the platen 175 along path 183, such that gravity aids in moving the workpiece 114 downward toward the alignment features 198. However, gravity cannot be used to perform alignment in the orthogonal direction, as the workpiece support 116 does not rotate such that gravity can assist in the alignment with features 197. Therefore, more complex, and potentially manual, alignment is required to properly align a workpiece and a shadow mask with prior art workpiece supports.

Therefore, it would be beneficial if there were a mechanism and method for aligning a workpiece and a shadow mask with minimal intervention. It would be further advantageous if such a mechanism and method relied on gravity to perform the alignment of these components to minimize manual interaction and cost.

### SUMMARY

The problems of the prior art are overcome by the mechanism and method of this disclosure. A workpiece support is defined whereby the platen, and thus the workpiece, can be tilted about at least two axes, which allows gravity to align the workpiece with a shadow mask in two orthogonal directions. In some embodiments, the workpiece support utilizes an axis of rotation that is orthogonal to the surface of the workpiece, in conjunction with a second axis that is parallel to the surface of the workpiece. Additionally, a method of aligning the workpiece using this workpiece support is also disclosed. Further, the workpiece support can be utilized to remove the workpiece from the support after implantation is completed.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 represents a traditional ion implantation system;

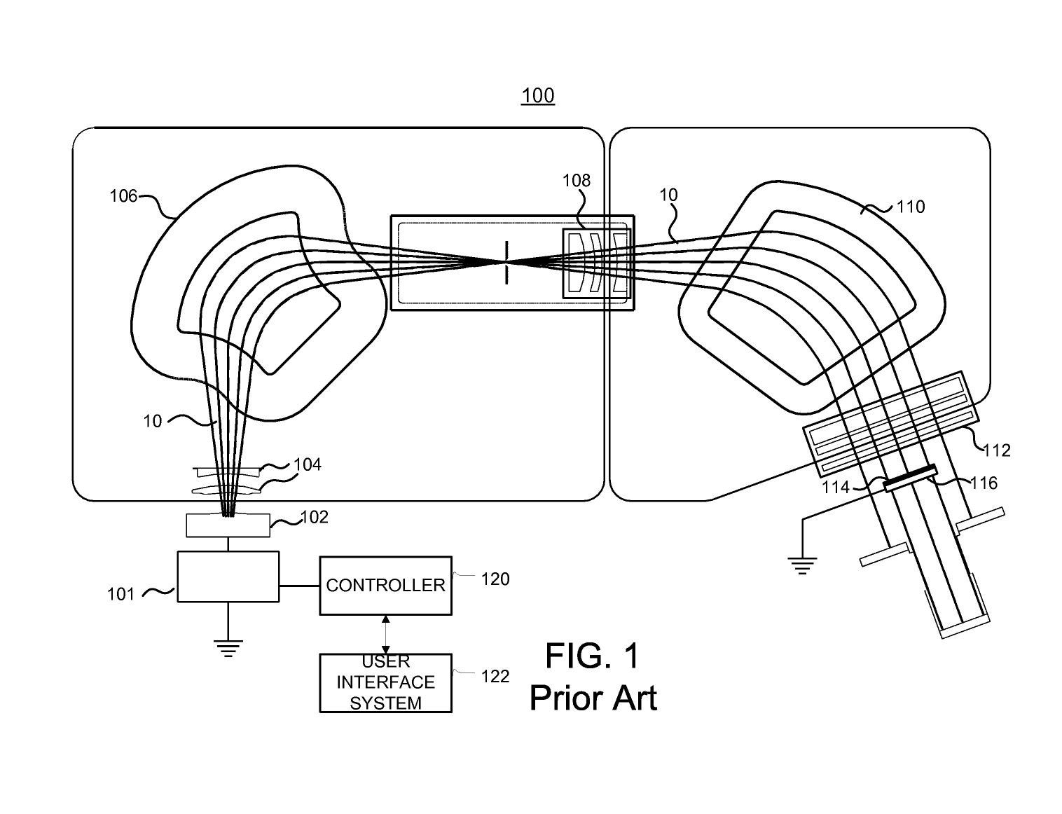

FIG. 2 represents a block diagram showing a workpiece support;

FIG. 3 represents a workpiece support having features for aligning a shadow mask and a workpiece;

FIG. 4 represents three dimensions relative to a workpiece;

FIG. 5 represents a workpiece support according to one embodiment;

FIG. 6 represents the workpiece support of FIG. 5 rotated above the y-tilt axis;

FIG. 7 is an exaggerated view of the workpiece and shadow mask shown in FIG. 6;

FIG. 8 represents the workpiece support of FIG. 5 rotated above the x-tilt axis;

FIG. 9 represents the workpiece support of FIG. 5 rotated about both the x-tilt and y-tilt axes; and

FIG. 10 represents the workpiece support of FIG. 5 vertically oriented to allow implantation.

### DETAILED DESCRIPTION

In the present disclosure, several embodiments of an apparatus and a method for aligning a workpiece and a shadow mask are introduced. For purpose of clarity and simplicity, the present disclosure will focus on an apparatus and a method for aligning a workpiece that is processed by a beam-line ion implanter. Those skilled in the art, however, may recognize that the present disclosure is equally applicable to other types of processing systems including, for example, a plasma immersion ion implantation (“PIII”) system, a plasma doping (“PLAD”) system, an etching system, an optical based processing system, and a chemical vapor deposition (CVD) system. As such, the present disclosure is not to be limited in scope by the specific embodiments described herein.

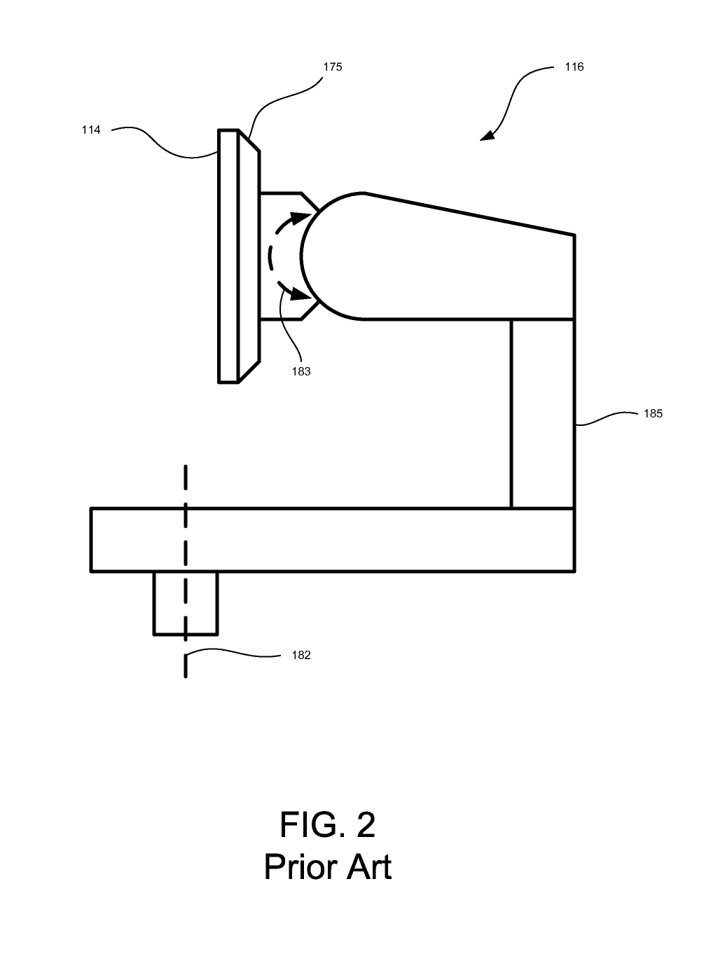

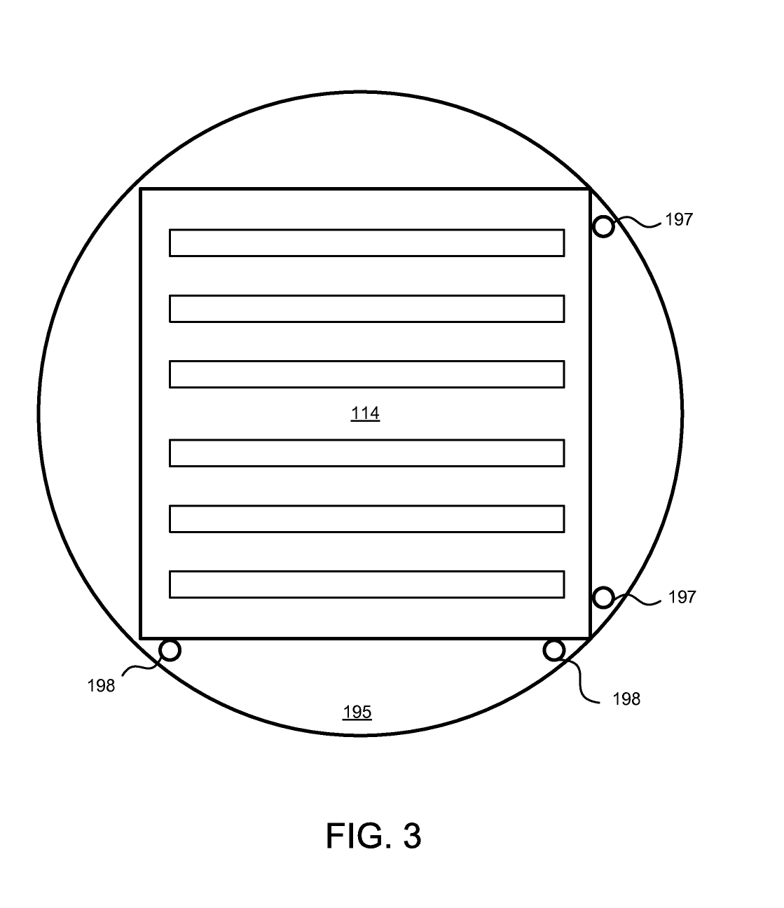

As described above in FIGS. 2 and 3, current workpiece supports allow the workpiece to be rotated in two directions. Typically, when the workpiece support is rotatable in two directions, one axis is the major axis, while the other is the minor or subordinate axis. In other words, rotation about one axis (the minor axis) does not affect the orientation of the major axis. Looking at FIG. 2, note that rotation about the x-tilt axis (i.e. movement along path 183) does not affect the orientation of the second axis 182. However, movement about the second, or vertical, axis 182 changes the orientation of the x-tilt axis. As shown in FIG. 2, the x-tilt axis is orthogonal to the surface of the page. However, if there were a quarter)(90°) turn about the second, or vertical, axis 182, the x-tilt axis would be parallel to the surface of the page. Thus, in this embodiment, the second, or vertical, axis 182 is the major axis. Because of this, gravity-based alignment is only possible in one dimension. As stated above, the workpiece support 116 of FIG. 2 allows gravity-based alignment with respect to features 198 (See FIG. 3). However, the workpiece support 116 cannot be rotated such that gravity can be used to align the workpiece 114 with features 197 (See FIG. 3).

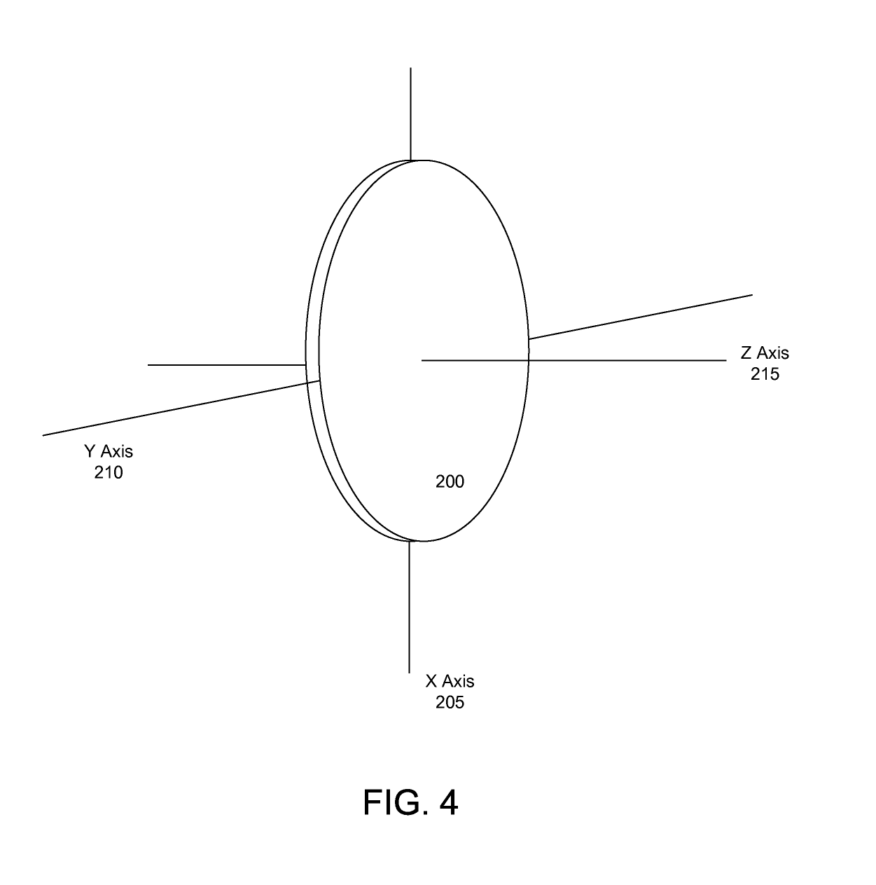

Thus, to allow alignment of the workpiece in two dimensions, the major axis is preferably not in the vertical direction. FIG. 4 shows a workpiece 200, having three defined axis. The x axis 205 and y axis 210 are both along the plane of the workpiece surface and are orthogonal to one another. The z axis 215 is orthogonal to the surface of the workpiece 200. To maximize the flexibility of various implantation angles and techniques, another desired feature is that the workpiece 200 can preferably be tilted about both axis 205, 210 that are parallel to its surface. This allows the workpiece 200 to be oriented in any position relative to the ion beam.

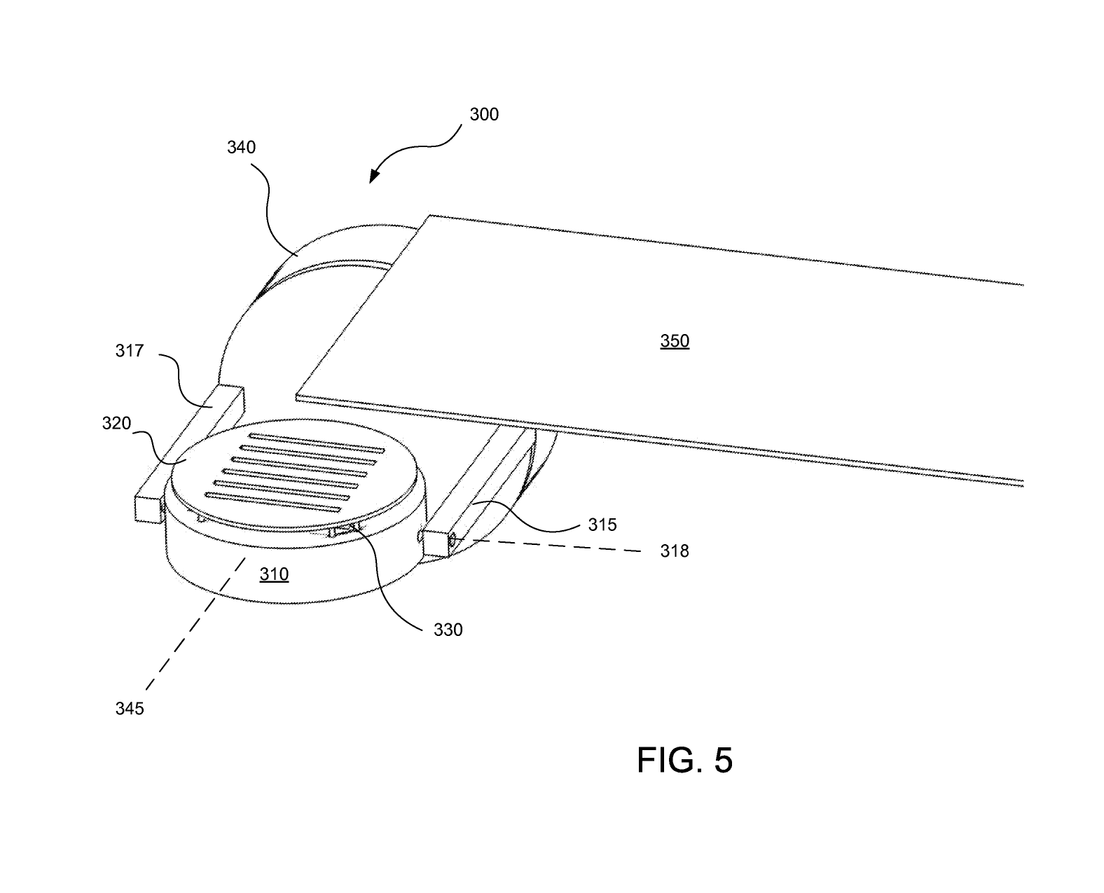

FIG. 5 shows a first embodiment of a workpiece support that meets these requirements. The workpiece support 300 includes a platen 310, which is rotatably mounted on the distal ends of two extending arms 315, 317. In some embodiments, the arms 315, 317 are at least as long as the radius of the platen 310, so that the platen can freely rotate about the y-tilt axis 318. In other embodiments, the arms need not be as long as the radius, as the platen may have a limited range of motion. The mask 320 and workpiece 330 are placed on the top surface of the platen 310. As is done in the prior art, electrostatic force can be used to hold the workpiece 330 in place on the platen 310. The extending arms 315, 317 are connected at their proximate end to a rotatable disk 340. In some embodiments, the rotating disk 340 and the extending arms 315, 317 are of unitary construction. Rotatable disk 340 rotates about x-tilt axis 345. Preferably the y-tilt axis 318 and the x-tilt axis 345 are co-planar, such that the x-tilt axis 345 passes through the y-tilt axis 318, as shown in FIG. 5.

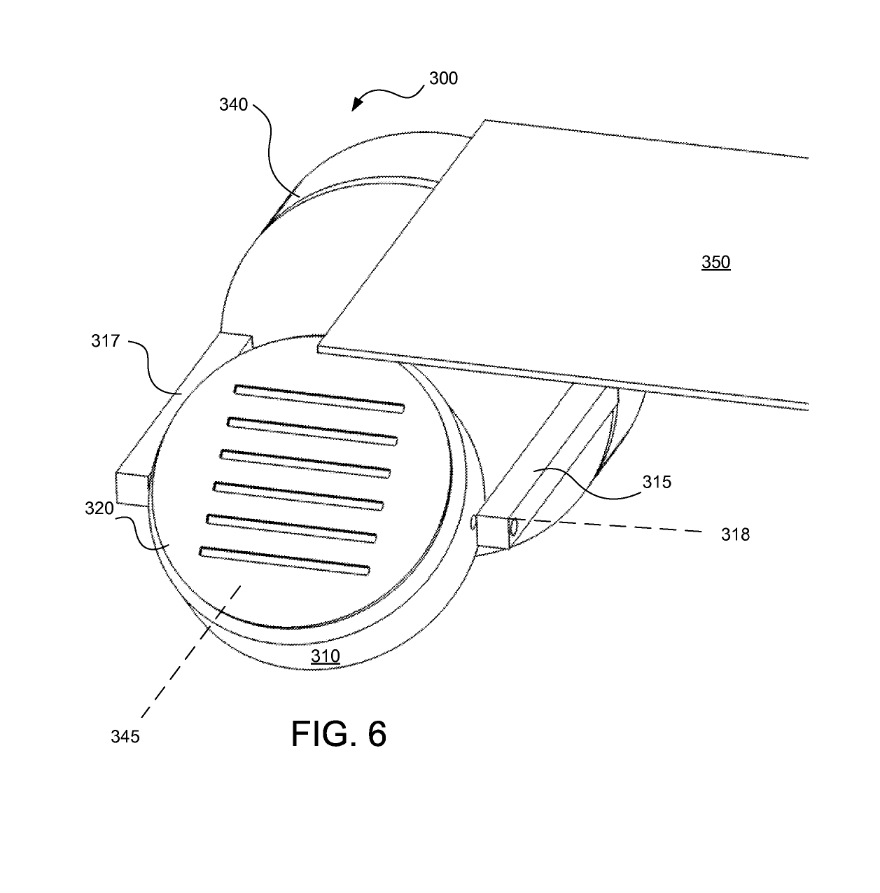

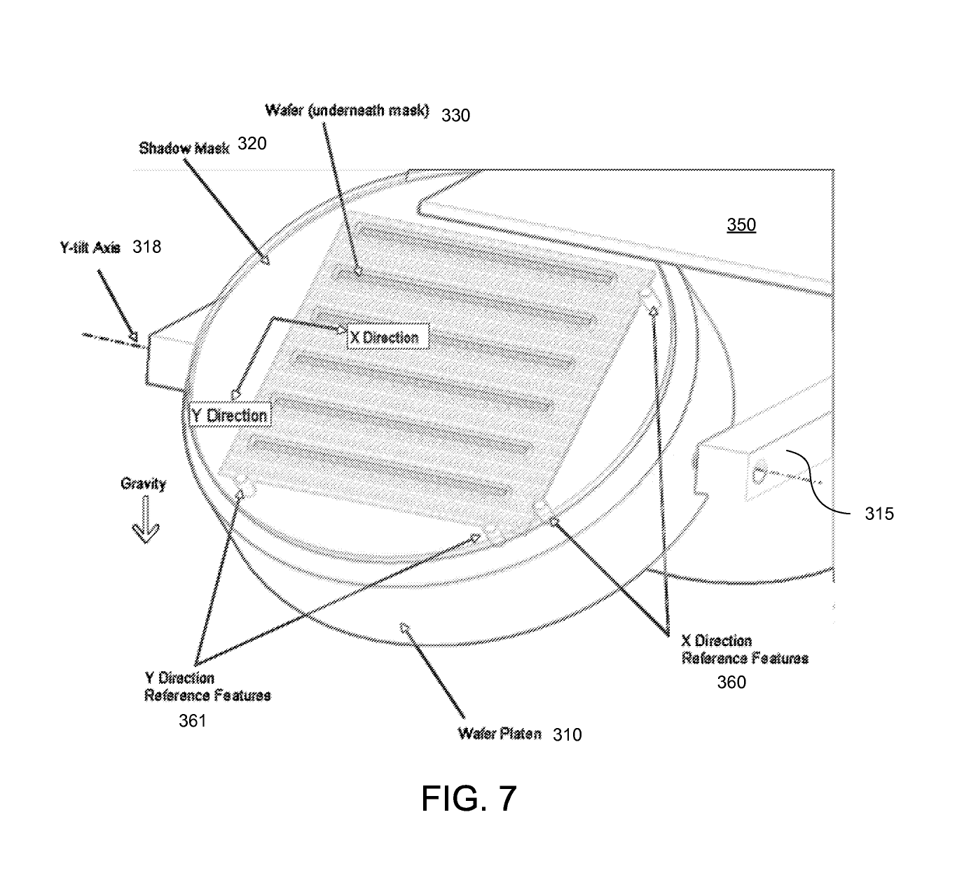

FIG. 5 shows the platen oriented such that the workpiece 330 is horizontal. Note that ion beam 350 is emanating from a source (not shown) positioned to the right, relative to the workpiece support 300. FIG. 6 shows the platen 310 rotated downward due to rotation about the y-tilt axis 318. FIG. 7 shows an expanded view of the workpiece 300 in this rotated position. Note that alignment features 360, 361 exist which are used to align the workpiece 330 to the shadow mask 320 in the x and y dimensions, respectively. When the platen 310 is rotated about the y-tilt axis 318, gravity-assisted alignment can be used with respect to alignment features 361.

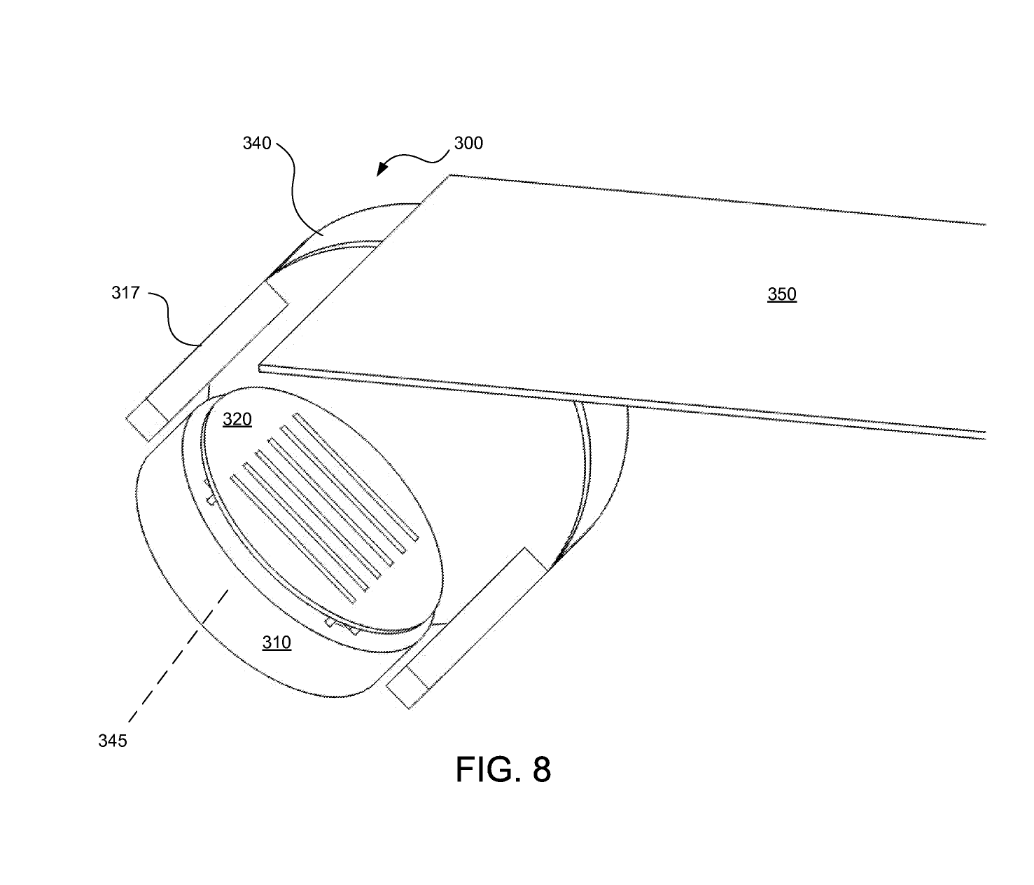

Returning to FIG. 5, the platen 310 can also be rotated about the x-tilt axis 345. FIG. 8 shows the platen 310 and workpiece 330 rotated about the x-tilt axis 345. In this orientation, gravity assisted alignment can be performed with respect to alignment features 360 (See FIG. 7).

Thus, by rotating the workpiece about both the y-tilt axis 318 and the x-tilt axis 345, it is possible to use gravity assisted alignment in both orthogonal dimensions (x and y) of the workpiece surface. It should be noted that the order in which the two rotations occur is not important; either axis can be rotated first. In some embodiments, both axes are rotated simultaneously. Once proper alignment has been achieved, an electrostatic field can be applied to hold the workpiece 330 in the proper position on the platen 310.

In this embodiment, the major axis is horizontal with respect to the ground, thereby allowing multiple alignments to be performed. The minor axis can be any axis orthogonal to that major axis. Thus, other embodiments of the workpiece support 300 are possible. In some embodiments, the minor or subordinate axis is vertical or horizontal.

Returning to FIG. 8, the workpiece can be implanted by the ion beam 350 by rotating the platen 310 about the x-tilt axis 345 such that the top surface of the workpiece 330 is facing the oncoming ion beam. Note that rotations about the x-tilt axis and y-tilt axis can be employed if angled implants are desirable. In the case of a scanned implant, the entire workpiece support 300 can be moved vertically or horizontally, as necessary.

To align a workpiece with a shadow mask, the following procedure may be used. First, the workpiece is placed on the platen 310, preferably while it is in the horizontal position, as shown in FIG. 5. After the workpiece 330 has been placed on the platen 310, the platen 310 is then rotated about the y-tilt axis 318, as shown in FIG. 6. This rotation causes the workpiece 330 to move downward toward alignment features 361, thereby aligning the workpiece 330 and shadow mask 320 in one direction. The platen 310 may be moved to a position which is at an angle of about 60 degrees relative to the horizontal. Angles that are shallower may also be effective in allowing the workpiece 330 to move. This position may be held for between 0.1 and 0.2 seconds to allow the workpiece 330 time to slide to the desired position. Other amounts of time may also be effective.

Once the workpiece 330 is in place, the electrostatic field can be applied to the platen 310, thereby holding the workpiece 330 in this position. In some embodiments, the platen 310 is then returned to the horizontal position, as shown in FIG. 5. In the case of one dimensional masks, such as horizontal or vertical lines, the alignment process is completed after alignment is completed in one orientation.

In the case of two dimensional masks, the workpiece must be aligned in the orthogonal direction. The platen is then rotated about the x-tilt axis 345 to allow alignment in this direction. In some embodiments, the platen is moved to a position that is at an angle of about 60 degrees relative to the horizontal, although other angles may also be effective. The electrostatic field is disabled to allow the workpiece 330 to slide to the desired position. After the platen 310 is held in the position sufficiently long, such as between 0.1 and 0.2 seconds, the electrostatic field is applied to hold the workpiece 330 in place. At this time, the workpiece 330 and the shadow mask 320 are aligned and ion implantation may begin.

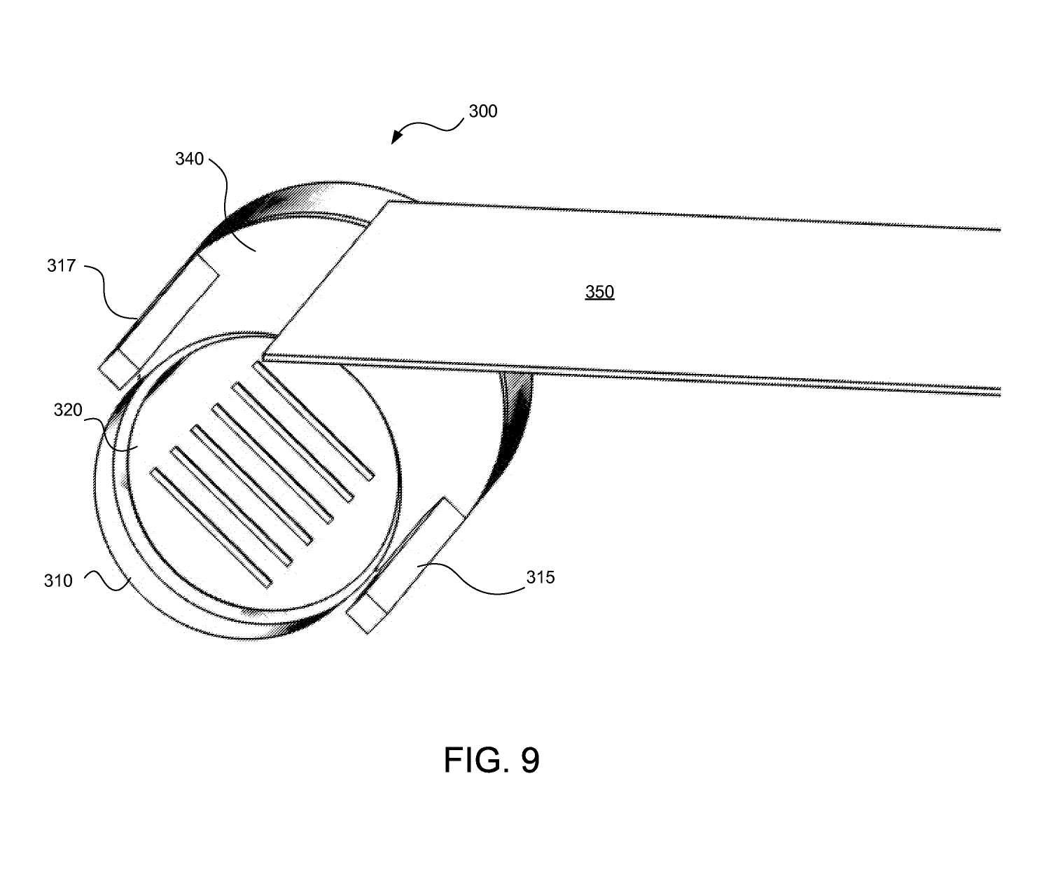

In some embodiments, it may be advantageous to tilting the platen 310 about the x and y axes simultaneously. FIG. 9 shows a workpiece rotated about both the x and y axes simultaneously. In this embodiment, the platen 330 is rotated about both axes simultaneously so that the workpiece 310 can move toward the alignment features 360,361 (see FIG. 7). After the workpiece 310 is placed on the platen 330, the platen 330 is rotated about both axes by about 60 degrees in both directions. In some embodiments, shallower angles may be used to perform the alignment. Once properly rotated, the workpiece 310 will move downward due to the force of gravity. This downward movement aligns the workpiece 310 to both the horizontal and vertical alignment features 2360, 361. The platen 330 is left in this rotated position for between 0.1 and 0.2 seconds, although other amounts of time may also be effective. Once the workpiece 310 is aligned, the electrostatic force may be applied to hold the workpiece 310 in place.

Once the workpiece 310 is properly aligned to the shadow mask 320, the workpiece may be implanted.

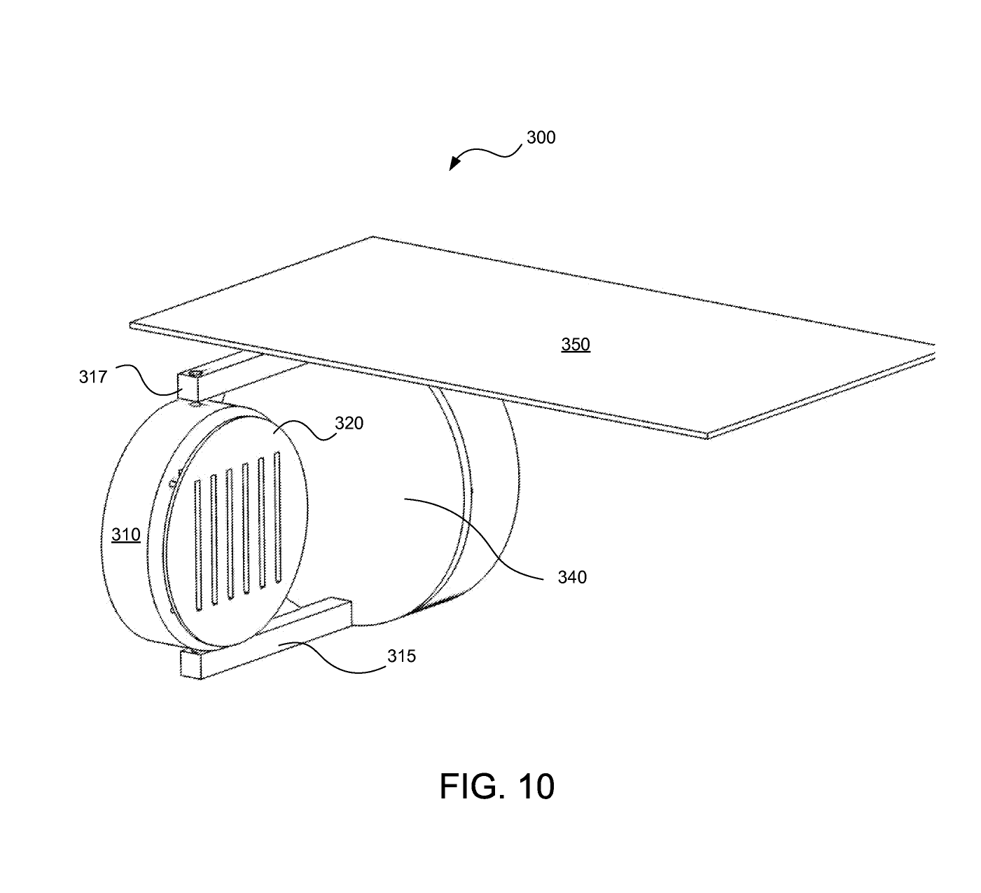

For a non-angled implant, the platen 310 is rotated 90° so that it is oriented vertically, as shown in FIG. 10. For angled implants, the platen 310 can be rotated about the x-tilt axis, the y-tilt axis or both, as required. As stated above, the workpiece support 300 may be moved vertically (or horizontally) to allow scanned implants.

The workpiece support 300 can also be used to dismount the workpiece. Note that, as shown in FIG. 7, the alignment features 360, 361 are only present on one side of the platen 310. Thus, by rotating the platen 310 in the opposite direction, away from the alignment features, gravity can be used to allow the workpiece 330 to slide away from the features and off of the platen 310 if desired. This can be done by rotation about the x-tilt, the y-tilt axis or both, as desired.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes.

What is claimed is:

1. A workpiece support for holding and aligning a workpiece, comprising a platen having a top surface onto which said workpiece is placed, wherein said platen is rotatable about a first axis and a second, non-vertical, major axis.

2. The workpiece support of claim 1, wherein said second axis is horizontal with respect to ground.

3. The workpiece support of claim 1, further comprising a rotatable disk and a plurality of arms extending from said rotatable disk, wherein said platen is rotatably connected to said distal ends of said extending arms.

4. The workpiece support of claim 1, wherein said first axis is horizontal with respect to ground.

5. The workpiece support of claim 1, wherein said first axis is vertical with respect to ground.

6. A method of aligning a workpiece to a shadow mask, comprising:
placing a workpiece on a platen, wherein said platen is rotatable about two axis, including a non-vertical major axis;
tilting the platen about one of said axis so that gravity causes said workpiece to slide toward alignment features located on said platen;
tilting the platen about the second of said axis so that gravity causes said workpiece to slide toward alignment features located on said platen; and
holding said workpiece in place.

7. The method of claim 6, wherein said platen is returned to a horizontal position between said tilting steps.

8. The method of claim 6, further comprising tilting said workpiece about one of said axis in the direction opposite said alignment features to dismount said workpiece from said platen.

9. The method of claim 6, wherein electrostatic fields are used to hold said workpiece in place.

10. The method of claim 6, wherein said first and second tiling steps are performed simultaneously.
